(19) United States
(12) Patent Application Publication
(10) Pub. No.: US 2007/0080757 A1
(43) Pub. Date: Apr. 12, 2007

(54) Composite filter chip

(76) Inventors: Kazuhiro Yahata, Osaka (JP); Takashi Uno, Hyogo (JP); Naohiro Tsurumi, Kyoto (JP); Hiroyuki Sakai, Kyoto (JP)

Correspondence Address: MCDERMOTT WILL & EMERY LLP, 600 13TH STREET, N.W., WASHINGTON, DC, 20005-3096, US

(21) Appl. No.: 11/544,635

(22) Filed: Oct. 10, 2006

(30) Foreign Application Priority Data
Oct. 11, 2005 (JP) 2005-296197

(51) Int. Cl. H03H 9/70; H03H 9/72

(52) U.S. Cl. 333/133

(57) ABSTRACT

A composite filter chip includes a stacked chip made by stacking a first chip and a second chip. The first chip has a first filter circuit formed on the main surface thereof. The second chip has a second filter circuit formed on the main surface thereof.

### CROSS-REFERENCE TO RELATED APPLICATIONS

This application claims priority under 35 U.S.C. § 119 on Patent Application No. 2005-296197 filed in Japan on Oct. 11, 2005, the entire contents of which are hereby incorporated by reference.

### BACKGROUND OF THE INVENTION

(a) Fields of the Invention

The present invention relates to composite filter chips made by stacking filter chips, and in particular to composite filter chips used for duplexers and the like.

(b) Description of Related Art

In wireless communications equipment such as a cellular phone, filtering between an antenna terminal and an amplifier is required in order to avoid extraneous emission of transmitting wave, degradation in sensitivity caused by unwanted flow of transmitting wave into a receiving unit, image interference to the receiving unit, and the like. Conventionally, as a filter for such filtering, an interstage filter, a duplexer, and the like have been employed which use a surface acoustic wave (SAW) filter and a dielectric filter. In recent years, a film bulk acoustic resonator (FBAR) filter has been employed particularly in a system requiring steeper filter characteristics, such as a PCS (Personal Communication Services) having a narrow frequency separation between transmit and receive band frequencies.

SAW filters are filters in which an interdigital transducer is formed on a piezoelectric substrate to utilize surface acoustic wave propagating the surface of the piezoelectric substrate. In order to avoid obstructing the surface acoustic wave, it is necessary to form a cavity in the surface of the piezoelectric substrate.

Most of FBAR filters are filters in which resonators utilizing longitudinal acoustic resonance of a piezoelectric thin film are combined in a ladder form. The resonators used in the FBAR filter have a MIM (Metal-Insulator-Metal) structure in which metal electrodes sandwich both surfaces of the piezoelectric thin film. In order to avoid interrupting acoustic resonance occurring by the resonator, generally, sealing in packaging the filter is conducted in the state in which cavities are provided on the outer surfaces of the electrodes, respectively, or in which a cavity is provided on the electrode located on the top surface of the filter and an SMR (Solid Mounted Reflector) is provided under the electrode located on the bottom surface of the filter. Furthermore, it is necessary to hermetically seal the filter in order to prevent degradation in the electrodes and the piezoelectric film.

As mentioned above, the SAW filter and the FBAR filter have to be formed with cavities and hermetically sealed. Therefore, the SAW filter and the FBAR filter are mounted in the following manner.

### First Conventional Example

FIGS. 14A and 14B illustrate a duplexer using an FBAR filter according to a first conventional example. FIG. 14A shows a plan structure thereof, and FIG. 14B shows a cross-sectional structure thereof taken along the line XIVb-XIVb in FIG. 14A. Referring to FIG. 14, a transmitting filter chip 701 and a receiving filter chip 702 are flip chip bonded to a mounting substrate 703 with solder balls 706 interposed therebetween, respectively. The transmitting and receiving filter chips 701 and 702 are covered and hermetically sealed with a laminated film 704, and further resin-sealed with a sealing resin 705. The laminated film 704 is provided to block the sealing resin 705 from entering spaces created between the transmitting and receiving filter chips 701 and 702 and the mounting substrate 703 to secure cavities (see “Next-generation digital architecture technology series” Vol. 1 “The current state and future trend of the technologies toward realization of LSIs for single-chip cellular phones”, Apr. 15, 2005, part IV, p. 70-72).

### Second Conventional Example

FIGS. 15A and 15B illustrate a sealed FBAR filter chip according to a second conventional example. FIG. 15A shows a plan structure thereof, and FIG. 15B shows a cross-sectional structure thereof taken along the line XVb-XVb in FIG. 15A.

Referring to FIG. 15, the sealed FBAR filter chip includes: an FBAR filter chip 802 having a filter circuit formed on the main surface thereof, and a silicon microcap 801. The FBAR filter chip 802 and the microcap 801 are connected by a gold-plated terminal 803 and a sealing ring 805, and the main surface side of the FBAR filter chip is hermetically sealed. A filter terminal is taken from a via hole formed through the microcap 803. The via hole is also sealed with gold plating (see the seminar text of “Component Test Symposium in Agilent Symposium Week 2003” 2003, p. 1-22).

The two sealed FBAR filter chips are arranged side by side above the mounting substrate to fabricate a duplexer. In this case, since the FBAR filter chips have already been hermetically sealed, it is unnecessary to hermetically seal the whole of the duplexer.

However, wireless communications equipment requires two filter chips, that is, a transmitting filter chip and a receiving filter chip. Therefore, when the conventional filter chip is used as a filter for wireless communications equipment, the transmitting and receiving filter chips should be arranged side by side above the mounting substrate. With recent downsizing of cellular phones and the like, miniaturization of inside filters is also needed. However, the filter chips should be arranged in parallel, which causes the problem that the area occupied by the filter chips increases.

In particular, with the shift toward multiband for cellular phones, a greater number of filters have been required. This trend also brings about the problem that the area having the filter chips mounted further increases.

### SUMMARY OF THE INVENTION

An object of the present invention is to solve the conventional problems mentioned above and to provide a filter chip which can offer, in equipment employing a plurality of filter chips, a reduced area of the filter chips occupied in the equipment.

To attain the above object, a filter chip of the present invention is designed as a composite filter chip in which a plurality of filter chips are stacked.

To be more specific, a first composite filter chip according to the present invention is characterized by comprising a stacked chip made by stacking: a first filter chip having a first filter circuit formed on the main surface thereof; and a second filter chip having a second filter circuit formed on the main surface thereof.

With the composite filter chip of the present invention, the stacked chip having the two filter chips stacked therein is provided. Therefore, a circuit employing a plurality of filter chips, such as a duplexer, can be formed by a single composite chip. This circuit structure can provide a significantly reduced area of the duplexer or the like as compared to the case where a plurality of filter chips are arranged two dimensionally, and can control the area of the filter chips occupied in equipment to a small value.

Preferably, in the first composite filter chip, in the stacked chip, the surface of the first filter chip opposite to the main surface faces the surface of the second filter chip opposite to the main surface. In the stacked chip, the surface of the first filter chip opposite to the main surface may face the main surface of the second filter chip, or the main surface of the first filter chip may face the main surface of the second filter chip.

Preferably, in the first composite filter chip, the first filter chip has a plurality of first terminals which are formed on the main surface of the first filter chip and electrically connected to the first filter circuit, the second filter chip has a plurality of second terminals which are formed on the main surface of the second filter chip and electrically connected to the second filter circuit, and with via plugs penetrating the second filter chip, the second terminals are taken to the surface of the second filter chip opposite to the main surface, respectively. With this structure, wiring between the second filter chip and the mounting substrate can be carried out from the back surface of the second filter chip, so that mounting of the chip can be facilitated.

Preferably, in the above case, the stacked chip has a sidewall member which is provided between the first and second filter chips and which forms a cavity hermetically sealed between the first and second filter chips. With this structure, a space between the first and second filter chips can be made airtight, so that hermetic sealing can be simplified. This reduces the area required for hermetic sealing and concurrently simplifies the mounting process steps.

The first filter chip may have a plurality of first terminals which are formed on the main surface of the first filter chip and electrically connected to the first filter circuit. The second filter chip may have a plurality of second terminals which are formed on the main surface of the second filter chip and electrically connected to the second filter circuit. With via plugs penetrating the first filter chip, the first terminals may be taken to the surface of the first filter chip opposite to the main surface, respectively, and with via plugs penetrating the second filter chip, the second terminals may be taken to the surface of the second filter chip opposite to the main surface, respectively. With this structure, wiring of both of the first and second filter chips can be carried out from the back surfaces thereof.

Preferably, in the above case, the stacked chip may have a sidewall member which is provided between the first and second filter chips and which forms a cavity hermetically sealed between the first and second filter chips. With this structure, a space between the first and second filter chips can be made airtight, so that hermetic sealing can be eliminated. This reduces the area required for hermetic sealing and concurrently simplifies the mounting process steps.

Preferably, in the above case, the first composite filter chip further comprises a mounting substrate mounting the stacked chip, and the stacked chip is mounted to the mounting substrate in the state in which the chip is molded by resin. With this structure, as compared to the case where a package for hermetic sealing is used, the area occupied by the filter chip can be reduced to a small value.

Preferably, in the first composite filter chip, the first and second filter chips have quadrangular plan shapes, the first filter chip has a plurality of first terminals which are formed on the main surface of the first filter chip and along two facing sides of the first filter chip and which are electrically connected to the first filter circuit, the second filter chip has a plurality of second terminals which are formed on the main surface of the second filter chip and along two facing sides of the second filter chip and which are electrically connected to the second filter circuit, and the first and second filter chips are arranged in the orientations in which the facing sides having the first terminals formed thereon and the facing sides having the second terminals formed thereon intersect each other. With this structure, radio frequency coupling between the input-output terminals of the first and second filter chips can be suppressed.

Preferably, in the first composite filter chip, the first and second filter circuits are filter circuits for a duplexer.

Preferably, in the composite filter chip of the present invention, the first and second filter circuits are filter circuits for different frequency bands. With this structure, isolation between the input-output terminals of the first and second filter circuits can be enhanced.

Preferably, in the first composite filter chip, one of the first and second filter circuits is a transmitting filter circuit, and the other is a receiving filter circuit.

Preferably, in the composite filter chip of the present invention, the first and second filter circuits are transmitting filter circuits. The first and second filter circuits may be receiving filter circuits.

Preferably, in the first composite filter chip, at least one of the first and second filter chips has a quarter-wave phase shifter formed on the surface of the chip opposite to the main surface. With this structure, the area occupied by the chips can be reduced.

Preferably, in the first composite filter chip, at least one of the first and second filter circuits is formed of a film bulk acoustic resonator filter, and at least one of the first and second filter circuits may be formed of a surface acoustic wave filter.

Preferably, the first composite filter chip further comprises a mounting substrate mounting the stacked chip, the first filter chip is mounted to the mounting substrate by wireless bonding, and the second filter chip is mounted to the mounting substrate by wire bonding.

A second composite filter chip according to the present invention is characterized by comprising a stacked chip made by stacking: a filter chip having a filter circuit formed on the main surface thereof; and a semiconductor chip having a semiconductor circuit formed on the main surface thereof. With the second composite filter chip, the composite filter chip having the filter chip and the semiconductor chip stacked therein is provided. Therefore, the area occupied by the composite filter chip can be reduced. Moreover, the filter chip and the semiconductor chip are stacked with the main surface of the filter chip facing the back surface of the semiconductor chip, whereby the filter circuit can be hermetically sealed. This reduces the area necessary for hermetic sealing and also reduces the hermetic sealing process steps in the mounting.

### BRIEF DESCRIPTION OF THE DRAWINGS

FIGS. 1A and 1B illustrate a composite filter chip according to a first embodiment of the present invention. FIG. 1A is a plan view thereof, and FIG. 1B is a sectional view thereof taken along the line Ib-Ib in FIG. 1A.

FIG. 2 is a sectional view showing an exemplary mounting of the composite filter chip according to the first embodiment of the present invention.

FIGS. 3A and 3B illustrate a composite filter chip according to a second embodiment of the present invention. FIG. 3A is a plan view thereof, and FIG. 3B is a sectional view thereof taken along the line IIIb-IIIb in FIG. 3A.

FIGS. 4A and 4B illustrate a first filter chip used in the composite filter chip according to the second embodiment of the present invention. FIG. 4A is a plan view thereof, and FIG. 4B is a sectional view thereof taken along the line IVb-IVb in FIG. 4A.

FIGS. 5A and 5B illustrate a second filter chip used in the composite filter chip according to the second embodiment of the present invention. FIG. 5A is a plan view thereof, and FIG. 5B is a sectional view thereof taken along the line Vb-Vb in FIG. 5A.

FIGS. 6A and 6B illustrate a stacked chip used in the composite filter chip according to the second embodiment of the present invention. FIG. 6A is a plan view thereof, and FIG. 6B is a sectional view thereof taken along the line VIb-VIb in FIG. 6A.

FIG. 7 is a sectional view showing an exemplary mounting of the composite filter chip according to the second embodiment of the present invention.

FIGS. 8A and 8B illustrate a composite filter chip according to one modification of the second embodiment of the present invention. FIG. 8A is a plan view thereof, and FIG. 8B is a sectional view thereof taken along the line VIIIb-VIIIb in FIG. 8A.

FIGS. 9A and 9B illustrate a composite filter chip according to a third embodiment of the present invention. FIG. 9A is a plan view thereof, and FIG. 9B is a sectional view thereof taken along the line IXb-IXb in FIG. 9A.

FIG. 10 is a sectional view showing a composite filter chip according to one modification of the third embodiment of the present invention.

FIG. 11 is a block diagram showing a duplexer using a composite filter chip according to a fourth embodiment of the present invention.

FIG. 12 is a block diagram showing a duplexer for a multiband system using the composite filter chip according to the fourth embodiment of the present invention.

FIG. 13 is a plan view showing a composite filter chip provided with a phase shifter according to the fourth embodiment of the present invention.

FIG. 14 shows a filter chip according to a first conventional example. FIG. 14A is a plan view thereof, and FIG. 14B is a sectional view thereof taken along the line XIVb-XIVb in FIG. 14A.

FIG. 15 shows a filter chip according to a second conventional example. FIG. 15A is a plan view thereof, and FIG. 15B is a sectional view thereof taken along the line XVb-XVb in FIG. 15A.

### DETAILED DESCRIPTION OF THE PREFERRED EMBODIMENTS

### First Embodiment

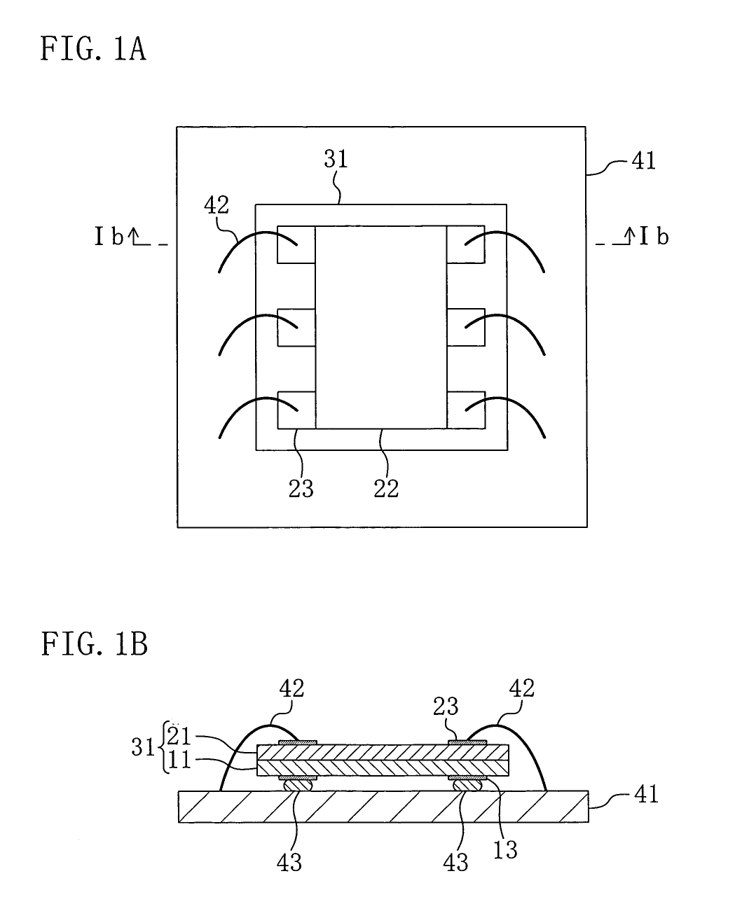

A first embodiment of the present invention will be described with reference to the accompanying drawings. FIGS. 1A and 1B illustrate a composite filter chip according to the first embodiment. FIG. 1A shows a plan structure thereof, and FIG. 1B shows a cross-sectional structure thereof taken along the line Ib-Ib in FIG. 1A.

Referring to FIG. 1, the composite filter chip of the first embodiment is composed of a stacked chip 31 mounted to a mounting substrate 41. The stacked chip 31 is formed by stacking a first filter chip 11 and a second filter chip 21.

The first filter chip 11 includes: a filter circuit 12 formed on the main surface (front surface) of a substrate made of silicon; and a plurality of pads 13 formed apart from each other on both sides of the filter circuit 12. The filter circuit 12 is, for example, a filter constructed by combining a plurality of film bulk acoustic resonators (FBARs) in a ladder form. The pads 13 are electrically connected to the filter circuit 12, and include, for example, two input/output terminals and four grounding terminals.

Likewise, the second filter chip 21 includes: a filter circuit 22 formed on the main surface (front surface) of a substrate made of silicon; and a plurality of pads 23 formed apart from each other on both sides of the filter circuit 22. The pads 23 are electrically connected to the filter circuit 22.

The first and second filter chips 11 and 21 are bonded so that the surfaces (back surfaces) of the substrates opposite to the main surfaces face each other. The bonding of the first and second filter chips 11 and 21 can be carried out using a known manner such as silver paste or adhesive.

The stacked chip 31 is mounted to the top of the mounting substrate 41 with the first filter chip 11 positioned lower. Each of the pads 13 of the first filter chip 11 is flip chip bonded with a solder ball 43 interposed between the pad and the substrate, while each of the pads 23 of the second filter chip 21 is wire bonded by a wire 42.

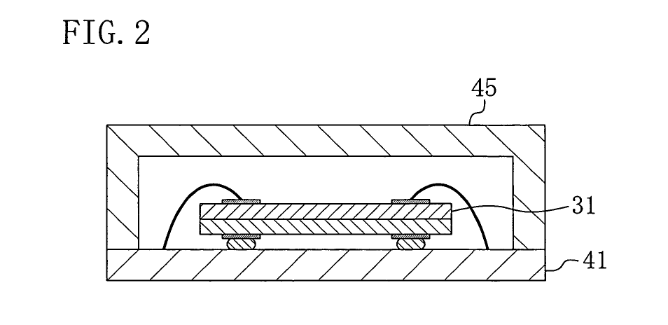

In addition, as shown in FIG. 2, finally, the composite filter chip of the first embodiment is hermetically sealed by an airtight package 45 made of ceramic or the like to prevent degradation of the filter circuits due to outside air invasion.

As described above, the composite filter chip of the first embodiment has the two filter chips arranged three-dimensionally. Thus, in forming a circuit requiring a plurality of filter chips, such as duplexers, a significantly reduced area of the filter chip occupied on the mounting substrate can be provided as compared to the case where two filter chips are arranged two dimensionally onto the mounting substrate.

In the first embodiment, the first and second filter chips 11 and 21 have about 0.7 to 1 mm-long sides in plan dimension, and thicknesses of about 100 to 500 μm. The sealing package for hermetically sealing the composite filter chip with the first and second filter chips 11 and 21 stacked therein has a plan dimension of about 2.5×2 mm to 1.4×1.1 mm, and a thickness of 1.5 to 2 mm.

### Second Embodiment

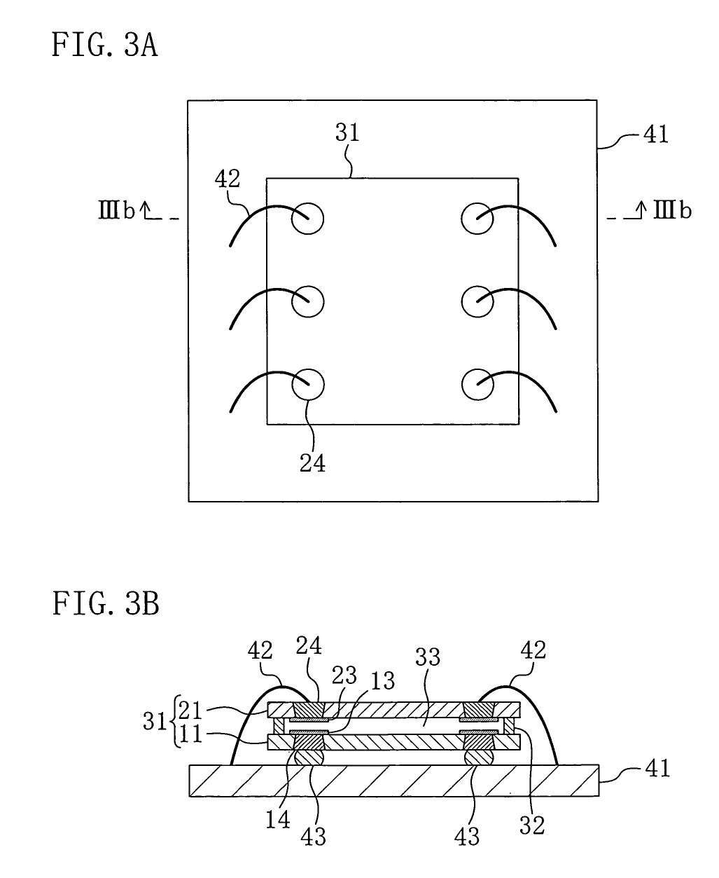

A second embodiment of the present invention will be described below with reference to the accompanying drawings. FIGS. 3A and 3B illustrate a composite filter chip according to the second embodiment. FIG. 3A shows a plan structure thereof, and FIG. 3B shows a cross-sectional structure thereof taken along the line IIIb-IIIb in FIG. 3A. The description of the components shown in FIG. 3 that are the same as those shown in FIG. 1 will be omitted by retaining the same reference numerals.

The composite filter chip of the second embodiment is formed by stacking the first filter chip 11 and the second filter chip 21 with the main surfaces thereof facing each other. The first and second filter chips 11 and 21 are bonded with a sidewall member 32 interposed therebetween. The sidewall member 32 is formed to surround the perimeters of the first and second filter chips 11 and 21, and a cavity 33 is created between the first and second filter chips 11 and 21. The cavity 33 is made airtight, so that the filter circuits 12 and 22 are hermetically sealed. Therefore, it is unnecessary to provide an additional space for hermetic sealing outside the stacked chip 31.

The first and second filter chips 11 and 21 are formed with via plugs 14 and 24 penetrating the substrate, respectively, and the pads 13 and 23 are taken to the back surfaces of the first and second filter chips 11 and 21, respectively. This facilitates wiring between the pads 13 and 23 and the mounting substrate 41. For example, it is sufficient that the first filter chip 11 is mounted by wireless bonding with a solder bump or the like interposed between the chip and the substrate and the second filter chip 21 is mounted by wire bonding.

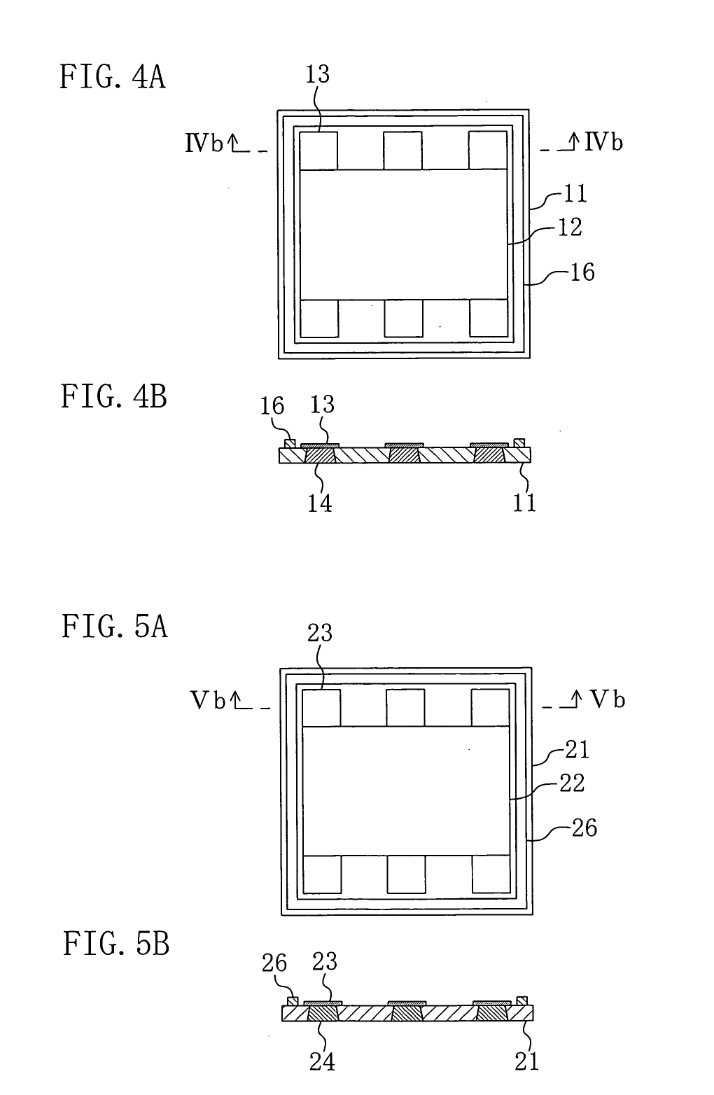

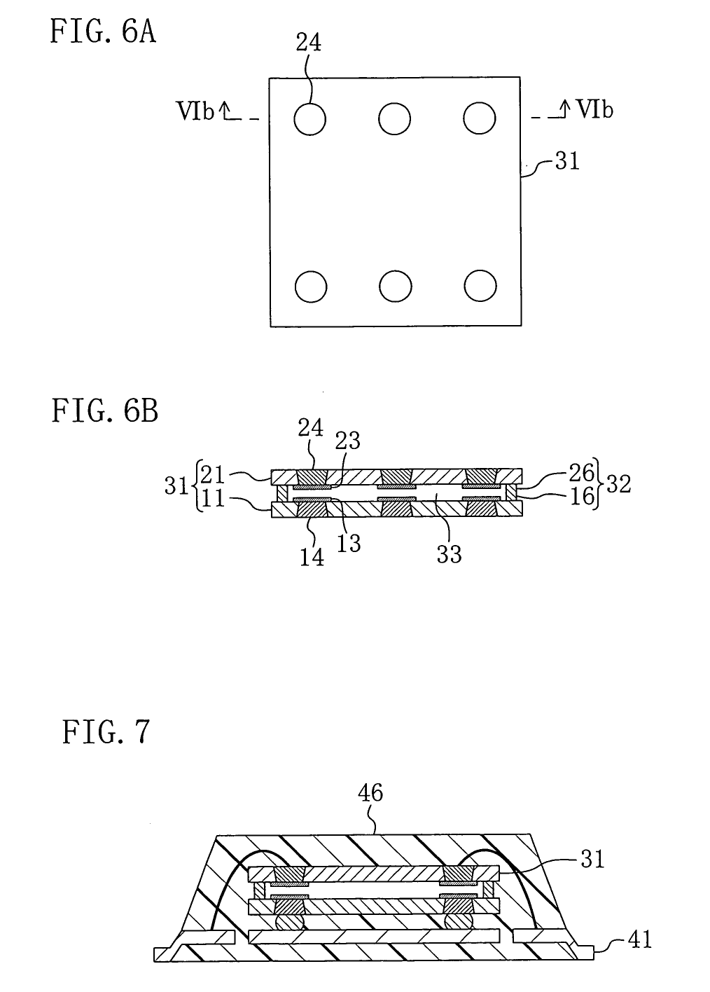

Next, a fabrication method of the stacked chip 31 according to the second embodiment will be described with reference to the accompanying drawings. FIGS. 4A and 4B illustrate a first filter chip before stacking. FIG. 4A shows a plan structure thereof, and FIG. 4B shows a cross-sectional structure thereof taken along the line IVb-IVb in FIG. 4A. FIGS. 5A and 5B illustrate a second filter chip before stacking. FIG. 5A shows a plan structure thereof, and FIG. 5B shows a cross-sectional structure thereof taken along the line Vb-Vb in FIG. 5A. FIGS. 6A and 6B illustrate a stacked chip made by stacking the first filter chip and the second filter chip. FIG. 6A shows a plan structure thereof, and FIG. 6B shows a cross-sectional structure thereof taken along the line VIb-VIb in FIG. 6A.

Referring to FIG. 4, the first filter chip 11 is formed in a substrate made of silicon. On the main surface side of the first filter chip 11, the filter circuit 12 is formed in the center portion thereof. The filter circuit 12 is constructed by combining a plurality of FBARs in a ladder form. On the main surface of the first filter chip 11, each side of the region thereof provided with the filter circuit 12 is formed with three pads 13, that is, provided with six pads 13 in all. The pads 13 are electrically connected to the filter circuit 12, and the functions as an input-output terminal and a grounding terminal function are allocated to the respective pads. Note that the number of pads is illustrative only, and it can be changed as appropriate according to the structure of the filter circuit.

With Via plugs 14, the pads 13 are taken to the back surface of the first filter chip 11, respectively. The via plugs 14 are each made of a conductive material which fills a via hole penetrating the first filter chip 11. It is sufficient that the via hole penetrating the filter chip is formed by a known method. For example, it is sufficient that it is formed by deep RIE (Reactive Ion Etching). Alternatively, it may be formed by wet etching or laser beam irradiation. It is sufficient that filling of the via hole with the conductive material is conducted by a known method such as gold plating. FIG. 4 illustrates an exemplary case where the conductive material fully fills the via hole, and alternatively it may be formed into a through hole covering the side wall of the via hole. The side wall of the via hole is provided with an insulating film (not shown) of silicon oxide, so that the via plug 14 is insulated from the substrate.

The perimeter of the main surface of the first filter chip 11 is formed with a first ring-shaped member 16 of gold to surround a region thereof provided with the filter circuit 12 and the pads 13. The first ring-shaped member 16 may be formed by gold plating or the like.

Likewise, referring to FIG. 5, the second filter chip 21 has a filter circuit 22, a plurality of pads 23, and a second ring-shaped member 26 formed on the main surface side of the substrate. With via plugs 24 penetrating the second substrate, the pads 23 are taken to the back surface of the second filter chip 21.

As shown in FIG. 6, the first and second ring-shaped members 16 and 26 are superposed on each other and then heated under pressure to bond the first and second filter chips 11 and 21, thereby fabricating the stacked chip 31. The bonding may be performed by ultrasonic irradiation or the like. The cavity 33 between the first and second filter chips 11 and 21 is made airtight by the sidewall member 32 formed by bonding the first and second ring-shaped members 16 and 26.

Since the filter circuits 12 and 22 are insulated from outside air, the stacked chip 31 of the second embodiment does not have to be hermetically sealed after mounting to the mounting substrate. Therefore, stacking of the filter chips can reduce the area occupied by the chip, and in addition to this, unnecessity of a package for hermetic sealing can significantly reduce the area occupied by the chip.

The composite filter chip of the second embodiment can be mounted, as shown in FIG. 7, by a resin package 46 in the manner in which the chip is molded by resin. In this case, it is sufficient that a lead frame is used for a mounting substrate 41.

### One Modification of Second Embodiment

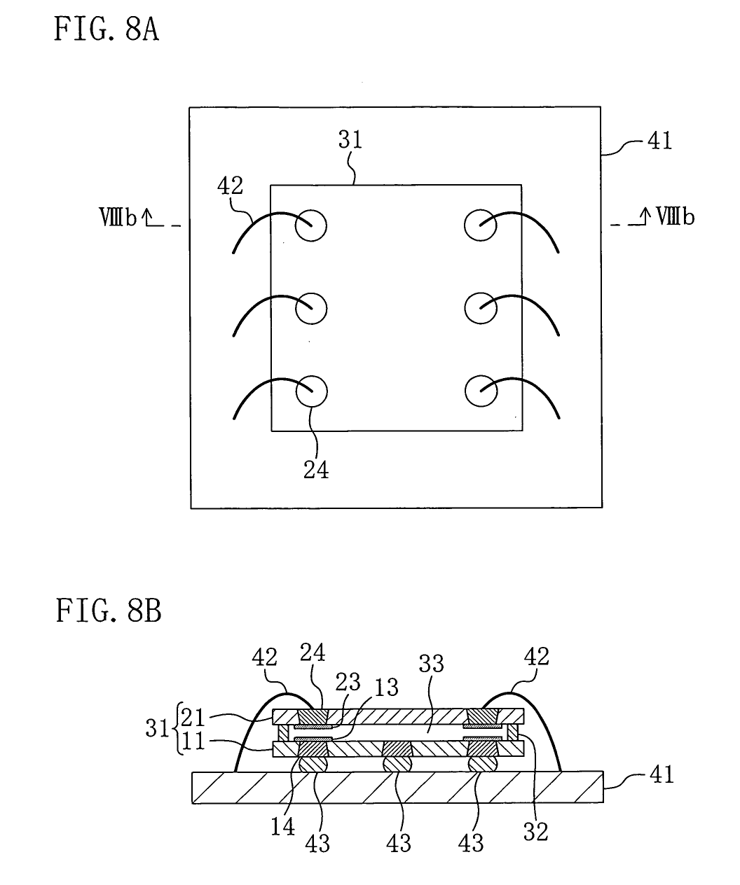

Hereinafter, one modification of the second embodiment of the present invention will be described with reference to the accompanying drawings. FIGS. 8A and 8B illustrate a composite filter chip according to this modification. FIG. 8A shows a plan structure thereof, and FIG. 8B shows a cross-sectional structure thereof taken along the line VIIIb-VIIIb in FIG. 8A. The description of the components shown in FIG. 8 that are the same as those shown in FIG. 3 will be omitted by retaining the same reference numerals.

The composite filter chip of this modification is fabricated by stacking the first and second filter chips 11 and 12 to be oriented 90 degrees apart from each other.

For example, of three aligned pads of each of the first and second filter chips 11 and 21, one located at the center is used as an input-output terminal and the others located at both sides are used as a grounding terminal. In this case, as shown in FIG. 3, if the first and second filter chips 11 and 21 are superposed on each other, the input-output terminals of the two chips are positioned too close to each other. This probably produces radio frequency coupling between the input-output terminals to degrade the high-frequency property of the chips. However, like this modification, by superposing the first and second filter chips 11 and 21 so that the side of the first filter chip 11 having the pads 13 formed thereon passes across the side of the second filter chip 21 having the pads 23 formed thereon, the input-output terminal of the first filter chip 11 can be positioned appropriately away from the input-output terminal of the second filter chip 21. This prevents degradation in the characteristics of the chips due to produced radio frequency coupling between the input-output terminals.

### Third Embodiment

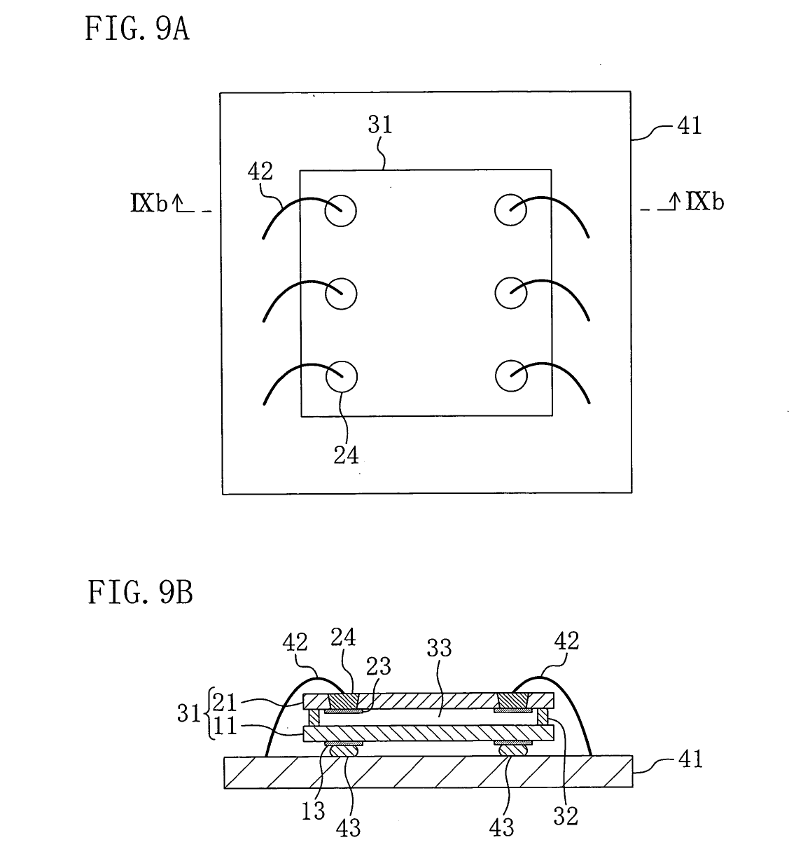

A third embodiment of the present invention will be described below with reference to the accompanying drawings. FIGS. 9A and 9B illustrate a composite filter chip according to the third embodiment. FIG. 9A shows a plan structure thereof, and FIG. 9B shows a cross-sectional structure thereof taken along the line IXb-IXb in FIG. 9A. The description of the components shown in FIG. 9 that are the same as those shown in FIG. 3 will be omitted by retaining the same reference numerals.

The composite filter chip of the third embodiment is formed by stacking the first and second filter chips 11 and 21 so that the back surface of the first filter chip 11 faces the main surfaces of the second filter chip 21. The first and second filter chips 11 and 21 are stacked with the sidewall member 32 interposed therebetween. The sidewall member 32 is formed to surround the perimeters of the first and second filter chips 11 and 21, and the cavity 33 is hermetically sealed. Thereby, the filter circuit 22 is hermetically sealed.

In this case, the filter circuit 12 is not made airtight. However, in mounting the stacked chip 31 to the mounting substrate 41, if the chip 31 is flip chip bonded so that the main surface of the first filter chip 11 faces the main surface of the mounting substrate 41, then it is sufficient to hermetically seal only a space between the first filter chip 11 and the mounting substrate 41. This enables an easy hermetical sealing. Moreover, an increase in the area occupied by the chip due to hermetic sealing can be suppressed. Furthermore, a via plug does not have to be provided through the first filter chip, so that the process steps for forming the first filter chip can be simplified.

### One Modification of Third Embodiment

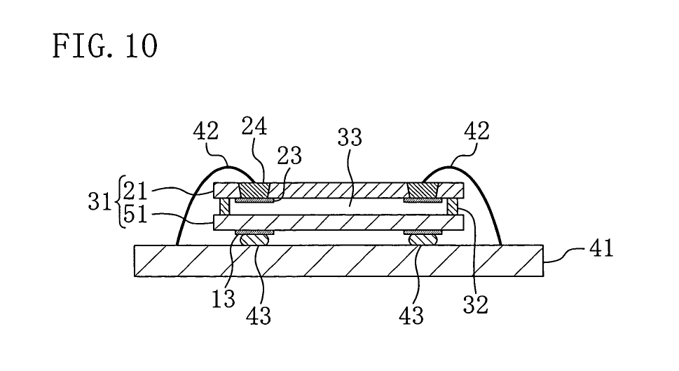

Hereinafter, one modification of the third embodiment of the present invention will be described with reference to the accompanying drawings. FIG. 10 shows a cross-sectional structure of the composite filter chip according to this modification. The description of the components shown in FIG. 10 that are the same as those shown in FIG. 9 will be omitted by retaining the same reference numerals.

As shown in FIG. 10, the composite filter chip of this modification has a semiconductor chip 51 stacked instead of the first filter chip 11. The semiconductor chip 51 does not have to be hermetically sealed, so that the area occupied by the composite filter chip can be reduced and the fabrication steps can be simplified.

Any chip can be employed as the semiconductor chip 51. The use of a chip for a power amplifier or a chip for a low noise amplifier in wireless communications equipment is advantageous to downsizing of the wireless communications equipment.

In FIG. 10, of the two chips, the semiconductor chip is flip chip bonded. Alternatively, the filter-chip may be flip chip bonded.

### Fourth Embodiment

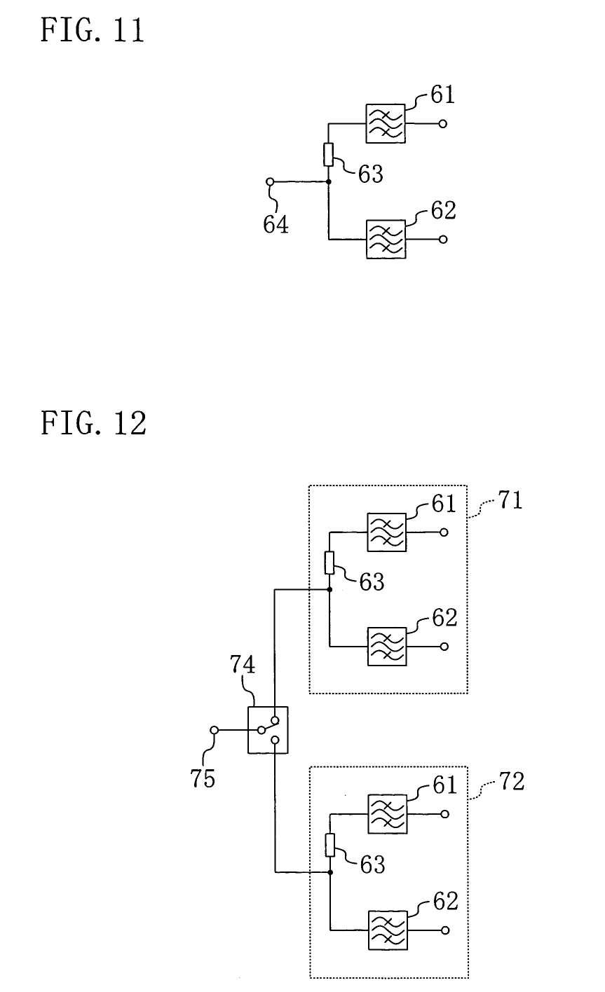

A fourth embodiment of the present invention will be described below with reference to the accompanying drawings. FIGS. 11 and 12 illustrate a circuit configuration of a duplexer employing a composite filter chip according to the fourth embodiment.

FIG. 11 shows a duplexer for a single band system used in 2 GHz W-CDMA, and the duplexer is configured using the composite filter chip shown in the embodiments and their modifications of the present invention. In this duplexer, one of composite filter chips having two filter chips stacked therein is employed as a receiving filter chip 61, and the other is used as a transmitting filter chip 62. One input-output terminal of each of the receiving filter chip 61 and the transmitting filter chip 62 is connected to an antenna terminal 64. The other input-output terminal of the receiving filter chip 61 is connected to a receiving circuit (not shown), and the other input-output terminal of the transmitting filter chip 62 is connected to a transmitting circuit (not shown). In order to prevent unwanted flow of a transmitting signal into the receiving circuit, the receiving filter chip 61 is connected to the antenna terminal 64 with a quarter-wave phase shifter 63 interposed therebetween.

With the above structure, a duplexer occupying a small area can be provided. Furthermore, by employing the composite filter chip or the like of the second embodiment, the need for hermetic sealing can be eliminated. Moreover, by employing the composite filter chip according to one modification of the second embodiment, isolation between the input-output terminals can be enhanced.

FIG. 12 shows an exemplary duplexer for a multiband system, which is fabricated by combining two composite filter chips shown in the embodiments and their modifications of the present invention. Referring to FIG. 12, the duplexer for the multiband system is composed of a 900 MHz duplexer 71, a 1.7 GHz duplexer 72, and an IC switch 74 serving as a single pole double throw switch.

The multiband duplexer transmits and receives signals in the manner in which the antenna terminal 75 is connected to an antenna and the IC switch 74 selects respective bands. For a cellular phone having the multiband duplexer mounted, while one band is in use, the other band is generally in the off state from the viewpoint of consumption current and isolation of signals between the bands.

Thus, by allocating the two filter chips of the composite filter chip to different bands, respectively, either one of the two filter chips is set in the off state without fail. As a result, a significant isolation can be provided.

For example, one of the two composite filter chips is composed of the receiving filter chip of the 900 MHz duplexer 71 and the receiving filter chip of the 1.7 GHz duplexer 72, while the other is composed of the transmitting filter chip of the 900 MHz duplexer 71 and the transmitting filter chip of the 1.7 GHz duplexer 72.

With this structure, in each of the 900 MHz and 1.7 GHz duplexers, the transmitting filter chip and the receiving filter chip are spatially isolated from each other. Moreover, since at least either of the duplexers 71 and 72 is in the off state without fail, a significant isolation can be provided. Herein, the exemplary case has been shown where the receiving filter chips are combined and the transmitting filter chips are combined. Alternatively, the receiving filter chip and the transmitting filter chip included in the different-band duplexers may be combined.

Description has been made of the case where the multiband duplexer of the fourth embodiment is composed of the two-band duplexers, that is, the 900 MHz duplexer and the 1.7 GHz duplexer. Alternatively, it may be composed of three-band duplexers by adding, for example, a 2.0 GHz duplexer, or composed of four or more-band duplexers. The frequency band to be used may be set freely according to demand.

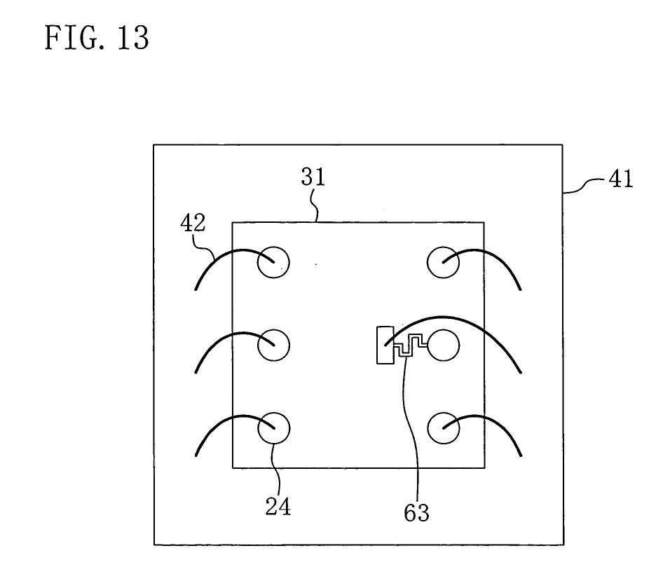

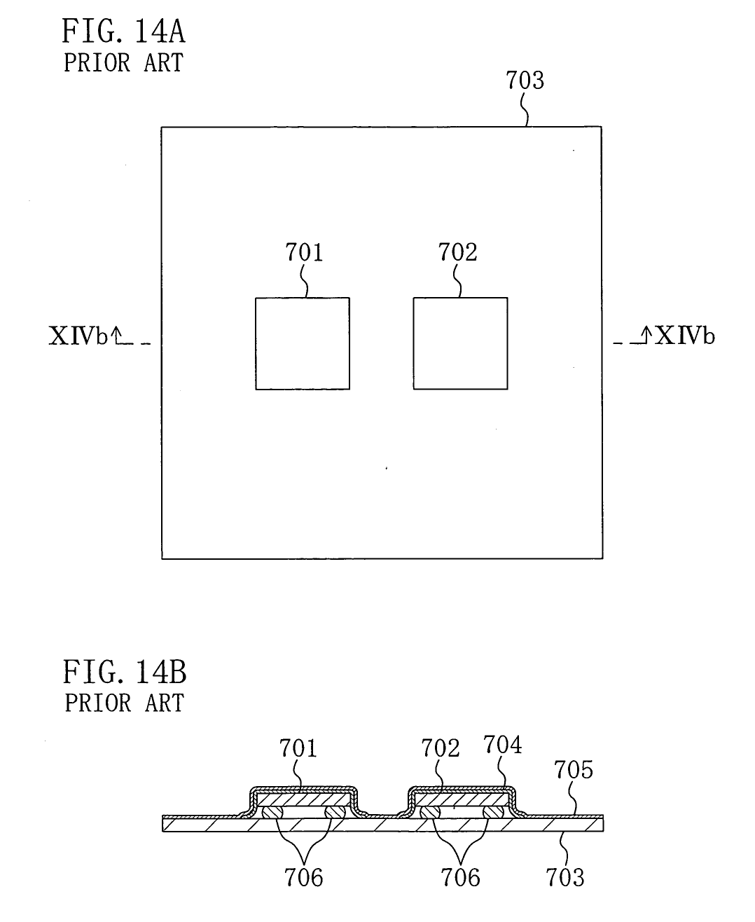

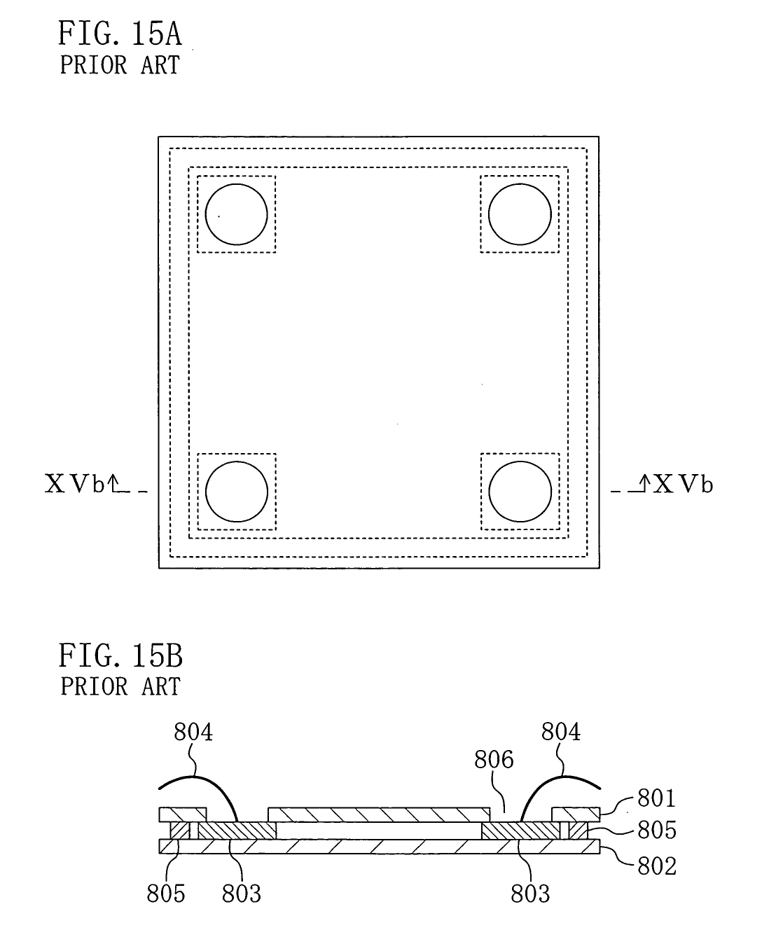

Moreover, as shown in FIG. 13, a phase shifter may be formed on the back surface of the filter chip. With this structure, the necessity to form the phase shifter on the mounting substrate side can be eliminated, which contributes to cost reduction and downsizing.

In the embodiments and their modification, description has been made of the exemplary case where the FBAR filter is used in the filter circuit. Alternatively, a SAW filter may be employed therein, or other structure may be employed in which an FBAR filter is used as one of the two filter chips and a SAW filter is used as the other. The construction of the filter circuit is not limited to the ladder form, and it may be a lattice form or the like.

As described above, the composite filter chip of the present invention can provide a filter chip which can offer, in equipment employing a plurality of filter chips, a reduced area of the filter chips occupied in the equipment. In particular, the composite filter chip of the present invention is useful for a composite filter chip used for a duplexer or the like.

What is claimed is:

1. A composite filter chip comprising a stacked chip made by stacking:
a first filter chip having a first filter circuit formed on the main surface thereof; and
a second filter chip having a second filter circuit formed on the main surface thereof.

2. The chip of claim 1,
wherein in the stacked chip, the surface of the first filter chip opposite to the main surface faces the surface of the second filter chip opposite to the main surface.

3. The chip of claim 1,
wherein in the stacked chip, the surface of the first filter chip opposite to the main surface faces the main surface of the second filter chip.

4. The chip of claim 3,
wherein the first filter chip has a plurality of first terminals which are formed on the main surface of the first filter chip and electrically connected to the first filter circuit,
the second filter chip has a plurality of second terminals which are formed on the main surface of the second filter chip and electrically connected to the second filter circuit, and
with via plugs penetrating the second filter chip, the second terminals are taken to the surface of the second filter chip opposite to the main surface, respectively.

5. The chip of claim 4,
wherein the stacked chip has a sidewall member which is provided between the first and second filter chips and which forms a cavity hermetically sealed between the first and second filter chips.

6. The chip of claim 1,
wherein in the stacked chip, the main surface of the first filter chip faces the main surface of the second filter chip.

7. The chip of claim 6,
wherein the first filter chip has a plurality of first terminals which are formed on the main surface of the first filter chip and electrically connected to the first filter circuit,
the second filter chip has a plurality of second terminals which are formed on the main surface of the second filter chip and electrically connected to the second filter circuit,
with via plugs penetrating the first filter chip, the first terminals are taken to the surface of the first filter chip opposite to the main surface, respectively, and
with via plugs penetrating the second filter chip, the second terminals are taken to the surface of the second filter chip opposite to the main surface, respectively.

8. The chip of claim 7,
wherein the stacked chip has a sidewall member which is provided between the first and second filter chips and which forms a cavity hermetically sealed between the first and second filter chips.

9. The chip of claim 8, further comprising a mounting substrate mounting the stacked chip,
wherein the stacked chip is mounted to the mounting substrate in the state in which the chip is molded by resin.

10. The chip of claim 1,
wherein the first and second filter chips have quadrangular plan shapes,
the first filter chip has a plurality of first terminals which are formed on the main surface of the first filter chip and along two facing sides of the first filter chip and which are electrically connected to the first filter circuit,
the second filter chip has a plurality of second terminals which are formed on the main surface of the second filter chip and along two facing sides of the second filter chip and which are electrically connected to the second filter circuit, and
the first and second filter chips are arranged in the orientations in which the facing sides having the first terminals formed thereon and the facing sides having the second terminals formed thereon intersect each other.

11. The chip of claim 1,
wherein the first and second filter circuits are filter circuits for a duplexer.

12. The chip of claim 11,
wherein one of the first and second filter circuits is a transmitting filter circuit, and the other is a receiving filter circuit.

13. The chip of claim 11,
wherein the first and second filter circuits are filter circuits for different frequency bands.

14. The chip of claim 13,
wherein the first and second filter circuits are transmitting filter circuits.

15. The chip of claim 13,
wherein the first and second filter circuits are receiving filter circuits.

16. The chip of claim 11,
wherein at least one of the first and second filter chips has a quarter-wave phase shifter formed on the surface of the chip opposite to the main surface.

17. The chip of claim 1,
wherein at least one of the first and second filter circuits is formed of a film bulk acoustic resonator filter.

18. The chip of claim 1,
wherein at least one of the first and second filter circuits is formed of a surface acoustic wave filter.

19. The chip of claim 1, further comprising a mounting substrate mounting the stacked chip,
wherein the first filter chip is mounted to the mounting substrate by wireless bonding, and
the second filter chip is mounted to the mounting substrate by wire bonding.

20. A composite filter chip comprising a stacked chip made by stacking: a filter chip having a filter circuit formed on the main surface thereof; and a semiconductor chip having a semiconductor circuit formed on the main surface thereof.
